(19) United States
(12) Patent Application Publication
(10) Pub. No.: US 2026/0324525 A1
(43) Pub. Date: Oct. 15, 2026

(54) ELECTRICAL COMPONENT PACKAGE WITH COMPONENT-ACCOMMODATING CAVITY

(71) Applicant: Microchip Technology Incorporated, Chandler, AZ (US)

(72) Inventors: Fernando Estrada, Mesa, AZ (US); Shesh Mani Pandey, Gilbert, AZ (US)

(73) Assignee: Microchip Technology Incorporated, Chandler, AZ (US)

(21) Appl. No.: 19/545,438

(22) Filed: Feb. 20, 2026

Related U.S. Application Data
(60) Provisional application No. 63/788,404, filed on Apr. 14, 2025.

(51) Int. Cl. H10W 90/00; H10W 70/40; H10W 70/68

(52) U.S. Cl. CPC H10W 90/756; H10W 70/424; H10W 70/682; H10W 70/481

(57) ABSTRACT

An electrical component package includes an electrical component, a frame, and a cavity in the frame, with the electrical component being at least in part aligned with the cavity.

### RELATED APPLICATIONS

This application claims the priority benefit under 35 U.S.C. § 119(e) of U.S. Provisional Patent Application Serial No. 63/788,404 entitled “Cavity Type Power Package Design,” filed Apr. 14, 2025. The entire content of the identified earlier-filed application is incorporated by reference as if fully set forth herein.

### TECHNICAL FIELD

The present disclosure relates to electrical component packages, and more particularly, the various examples described herein concern an electrical component package including a frame that supports an electrical component in at least partial alignment with a cavity in the frame.

### BACKGROUND

Electrical component packages commonly contain one or more electrical devices in a protective casing. Electrical devices found in electrical component packages include, but are not limited to, transistors, resistors, diodes, and capacitors. These packages can be electrically attached to larger electrical structures like printed circuit boards and are found in a wide variety of devices such as televisions, computers, and phones, without limitation. In order to fit in the aforementioned structures and others like them, electrical component packages may be limited to a certain height, restricting the configuration, placement, size, and/or number of electrical devices that can be fit inside the package.

This background discussion is intended to provide related information, and is not necessarily prior art.

### SUMMARY

Examples in this disclosure provide an electrical component package comprising an electrical component, an electrical connector electrically coupled with the electrical component, and a frame supporting the electrical component. The frame presents a cavity, and the electrical component is at least in part aligned with the cavity.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current technology will be apparent from the following detailed description of the various examples and the accompanying drawing figures.

### BRIEF DESCRIPTION OF THE FIGURES

Various examples of the current technology are described in detail below with reference to the attached drawing figures, wherein:

FIG. 1 is a perspective view of a semiconductor package design with leads and an encapsulating casing, in accordance with various examples of the present disclosure;

FIG. 2 is a perspective view of the semiconductor package shown in FIG. 1, taken from a generally opposite angle;

FIG. 3 is a perspective view of the semiconductor package similar to FIG. 1, but with the encapsulating casing removed;

FIG. 4 is an enlarged perspective view of the semiconductor package as depicted in FIG. 3, particularly illustrating the cavity of the lead frame and the components therein;

FIG. 5 is an enlarged perspective view of the semiconductor package nearly identical to FIG. 4, but illustrating the cavity of the lead frame shown in FIG. 4 with the other components removed;

FIG. 6 is a cross-sectional view of the semiconductor package with the casing removed, as shown in FIG. 3;

FIG. 7 is an enlarged cross-sectional view of the semiconductor package as shown in FIG. 6, particularly illustrating the semiconductor component located entirely in the cavity and the wires extending into the cavity for connection to the component;

FIG. 8 illustrates a cross-sectional view of an example of a semiconductor package, in which a device may be interposed in the cavity between the lead frame and the electrical component;

FIG. 9 is a perspective view of another example of a semiconductor package similar, particularly depicting a through-hole component package with a cavity in the lead frame; and

FIG. 10 is a perspective view of the semiconductor package shown in FIG. 9, but showing the package with the encapsulating casing.

The drawing figures do not limit the current technology to the specific examples disclosed and described herein. The drawings are not necessarily to scale, with emphasis instead being placed upon clearly illustrating the principles of the technology.

The hatch patterns on various components in the figures are meant to differentiate adjacent parts from each other. The appearance of the hatch patterns and any perceived similarities between them on different elements should not be interpreted as a statement on the material or structure of the elements.

### DETAILED DESCRIPTION

The following detailed description of the technology references the accompanying drawings that illustrate specific examples in which the technology can be practiced. The various examples are intended to describe aspects of the technology in sufficient detail to enable those skilled in the art to practice the technology. Other examples can be utilized and changes can be made without departing from the scope of the current technology. The following detailed description is, therefore, not to be taken in a limiting sense. The scope of the current technology is defined only by the appended claims, along with the full scope of equivalents to which such claims are entitled. In addition, it will be readily understood that the components of the examples as generally described herein and illustrated in the drawings could be arranged and designed in a wide variety of different configurations. Thus, the following description of various examples is not intended to limit the scope of the current disclosure but is merely representative of various examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Examples of the present disclosure relate to an electrical component package including an electrical component supported by a frame. The electrical component may comprise a diode, a capacitor, a resistor, a transistor, or a combination of these devices, without limitation. In various examples, the package may comprise one or more leads that electrically connect to the electrical component, as well as electrical connectors that form an electrical connection between the electrical component and the leads. The package may be encapsulated by a protective casing around the electrical component and at least part of the frame.

The frame of the package may include a cavity that the electrical component is aligned with. The cavity may allow for the use of thicker parts to be used for elements of the package like the electrical connectors without requiring an increase in the height of the package. The cavity may also allow additional electrical devices to be interposed between the frame and the electrical component without requiring an increase in the height of the package.

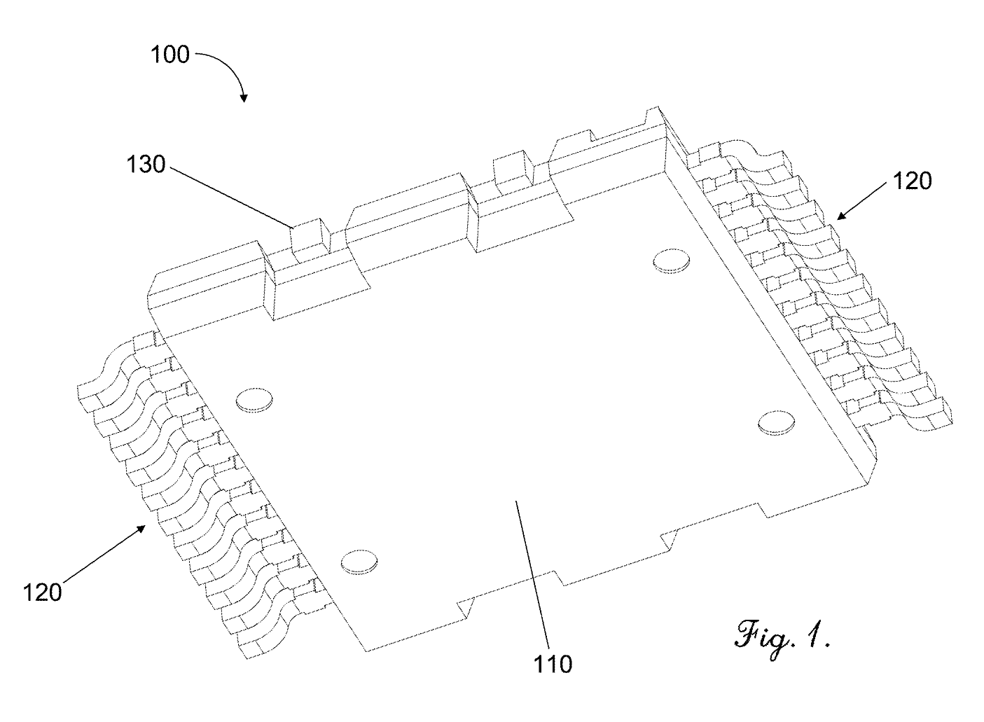

Turning initially to FIG. 1, an example electrical component package 100 may include a casing (or encapsulant) 110 surrounding at least part of a frame 130. In the illustrated example, the casing 110 is molded over the frame 130. The casing 110 may be formed of an electrically and thermally insulative material, although aspects of other examples contemplate casing materials that do not provide one or both of the insulative qualities. One suitable insulative casing material may be epoxy resin; however, as noted, certain aspects of the example package 100 contemplate other insulative or non-insulative casing materials. In the illustrated example, the frame 130 is partially exposed by the casing 110. The frame 130 may be made of a thermally conductive material, and the exposed portion thereof may be attached to a separate heat dissipation element (not shown). In various other examples, the frame may be entirely encapsulated within the casing.

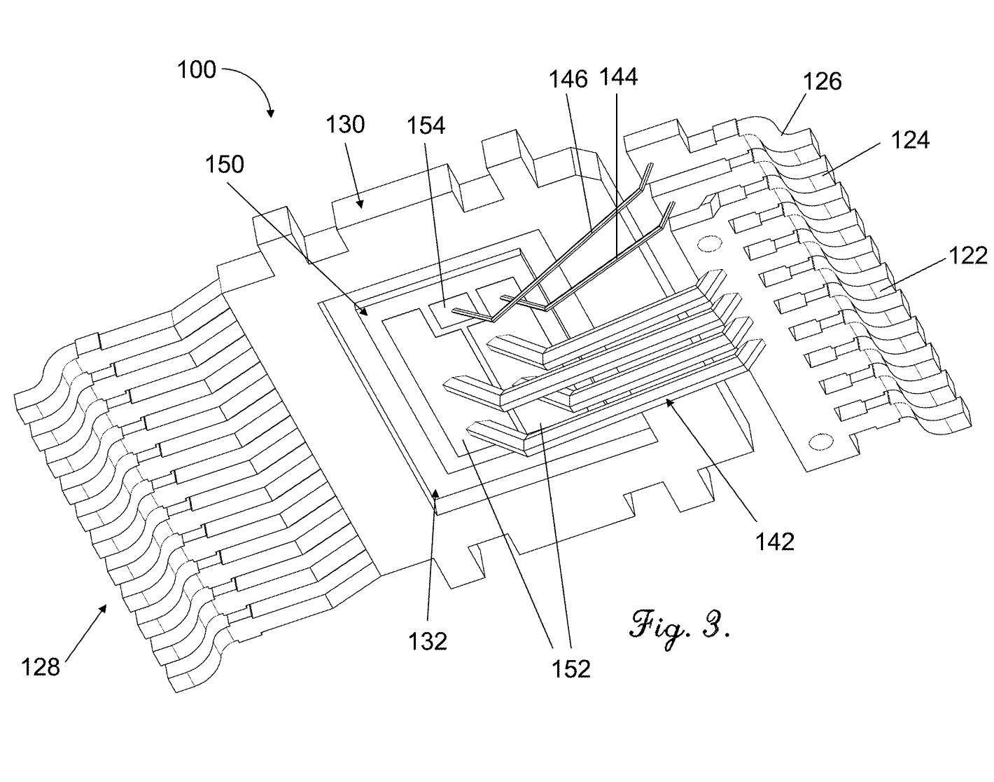

The package 100 may further include an electrical component 150, which is supported by the frame, and an electrical connector 120 electrically coupled to the electrical component 150 (see FIG. 3). In the illustrated example, the electrical connector comprises multiple leads 120 extending through the casing 110 to electrically connect with the electrical component 150. Part of the illustrated connector 120 is integrally formed with the frame 130. Additionally, according to certain examples and as will be described below, the frame 130 may function as part of the electrical connecter. Yet further, in the illustrated example, some of the leads 120 are physically spaced and electrically isolated from the frame 130. However, according to some examples (as explained below), the frame may alternatively be physically spaced and/or electrically isolated from the entirety of the electrical connector. In the illustrated embodiment, each of the leads 120 may take the form of a pin; however, according to certain examples, one or more of the leads may take the form of another type of leads or electrical connector, such as a solder ball.

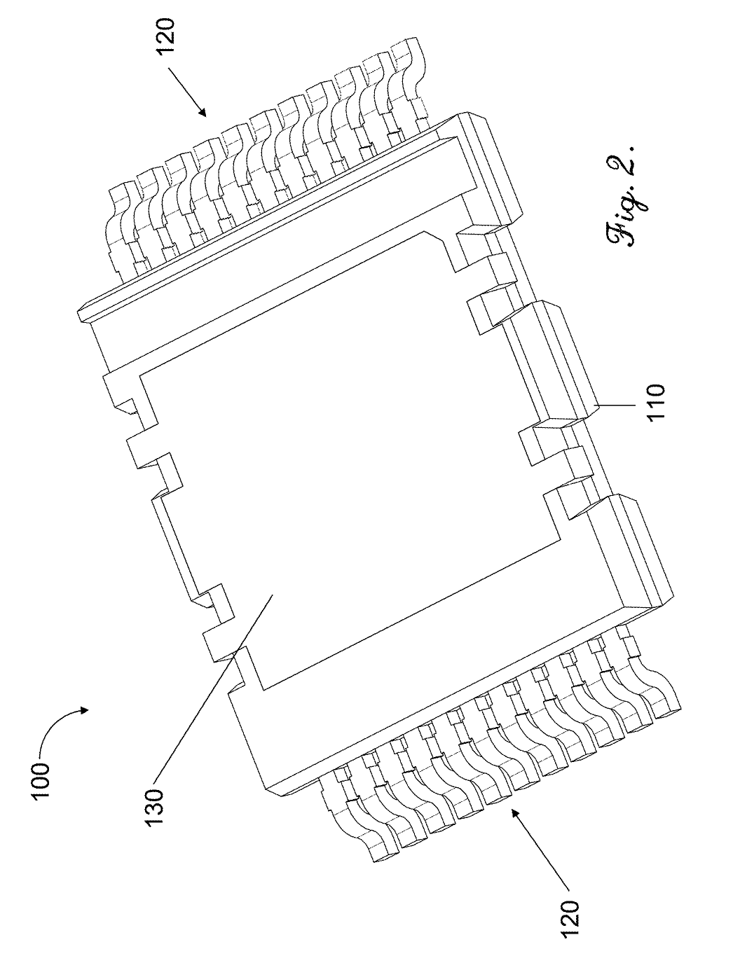

FIG. 3 illustrates the electrical component package embodiment 100 of FIGS. 1 and 2 with the casing 110 removed. In the illustrated example, the electrical component 150 comprises a metal-oxide-semiconductor field-effect transistor (MOSFET). However, those of ordinary skill in the art will appreciate that various other examples contemplate the use of one or more alternative electrical components(s) (such as a junction field effect transistor (JFET), diode, capacitor, die, etc.) as part of the package. With the illustrated MOSFET 150, the leads 120 may be subdivided into source leads 122, a Kelvin connection lead 124, a gate lead 126, and drain leads 128. The MOSFET 150 may be electrically connected to and placed in direct contact with the frame 130, such that the frame 130 may serve as the drain for the MOSFET 150. The MOSFET 150 may be electrically connected to the source leads 122 by source wires 142. The MOSFET 150 may be similarly connected to the Kelvin connection lead 124 by a Kelvin connection wire 144 and to the gate lead 126 by a gate wire 146. In the illustrated example, the frame 130 is made of an electrically conductive material (such as a suitable metal) and electrically connects the MOSFET 150 to the drain leads 128, which may be integrally formed with the frame 130. (The illustrated frame 130 consequently may form part of the electrical connector.) As noted, the MOSFET may be substituted for a different electrical component, and the leads and connections may be changed or rearranged to accommodate the different electrical component. The frame may also be made of an electrically insulative material, such that a different means for connecting the MOSFET to the drain leads, such as a wire(s) is provided.

The frame 130 may be provided with a cavity 132 which is configured to accommodate the MOSFET 150 . As will be appreciated and further described, the MOSFET 150 (or alternative electrical component) may be aligned (as described below) with the cavity 132. The cavity 132 thereby accommodates the MOSFET 150 by allowing the MOSFET to be received entirely or partially within the cavity, by allowing other devices to be associated with the MOSFET, and/or by allowing alternative electrical connections to the MOSFET, all of which may be accomplished without increasing the height of the package. The cavity 132 may have a rectangular cross-sectional shape, although other suitable cross-sectional shapes are within the ambit of other example packages. The outer margin of the cavity 132 is defined by the open end of the cavity (i.e., at the intersection of the cavity 132 with the surface of the frame 130 from which the cavity 132 extends). In the illustrated example, the MOSFET 150 is contained entirely within the cavity 132 and the wires 142, 144, and 146 extend into the cavity 132. In other examples, the MOSFET may be located entirely or partially above the outer margin of the cavity, in which case the electrical connector(s) may be located entirely outside the cavity. In one example, the presence of the cavity 132 may accommodate for the use of a MOSFET that would otherwise be too large to mount on the frame 130 without increasing the height of the package 100.

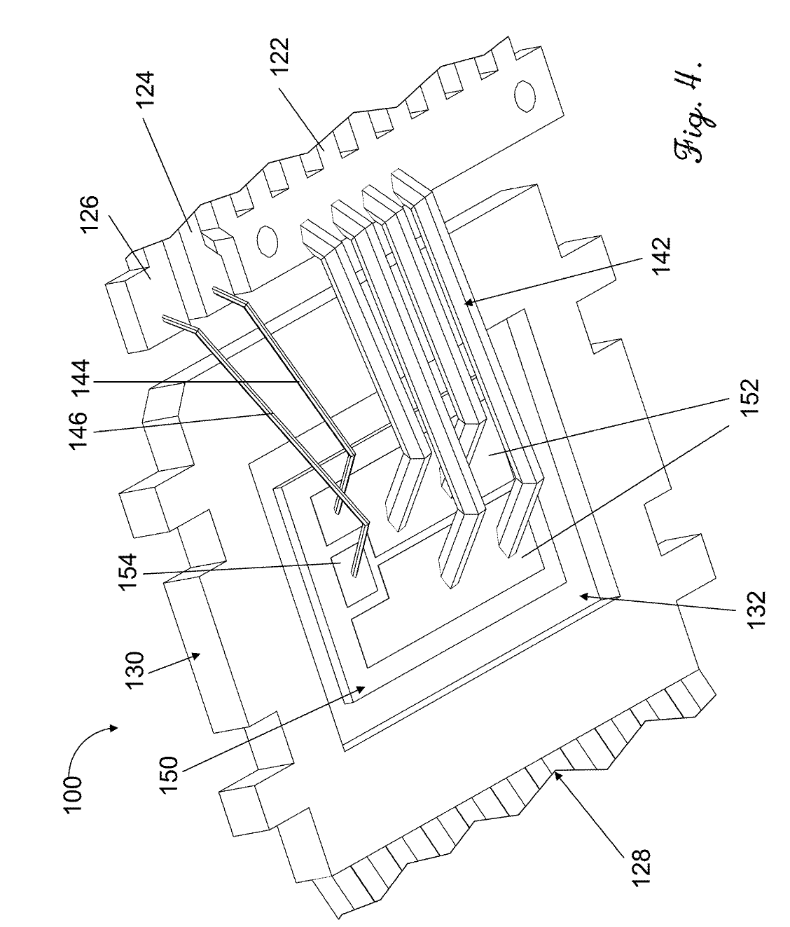

FIG. 4 is an enlarged view of the cavity 132, as shown in FIG. 3. As is often the case, the MOSFET 150 may include top side metallization in the form of source pads 152 and a gate pad 154. The source wires 142 electrically connect the source leads 122 to the source pads 152. Likewise, the Kelvin connection wire 144 electrically connects the Kelvin connection lead 124 to one of the source pads 152, and the gate wire 146 electrically connects the gate lead 126 to the gate pad 154.

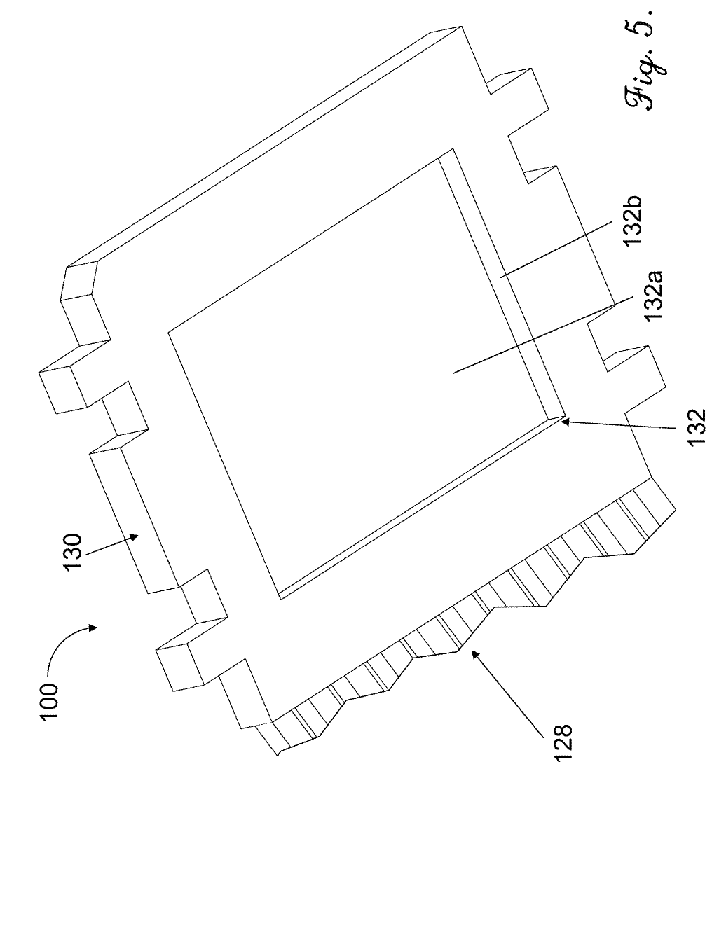

FIG. 5 illustrates a view similar to FIG. 4 with the MOSFET 150, the leads 120, and the various wires 142, 144, and 146 removed. As mentioned above, the illustrated cavity 132 has a rectangular cross-sectional shape such that the outer margin thereof (located at the corresponding surface of the frame 130) is similarly shaped. However, according to certain examples of the package, the cavity may have a variable cross-sectional shape that varies as the cavity extends from the surface, or the cavity cross-sectional shape and the outer margin shape may be otherwise dissimilar. The cavity may have a floor or base 132a that defines the inner terminal end of the cavity, such that the cavity is in the form of a recess and does not extend entirely through the frame. That is to say, the area within the cavity 132 (henceforth called the cavitary area) may have any depth and shape so long as it does not intersect with the outer surface opposite the surface that defines the outer margin of the cavity 132. In the illustrated example, the cavity 132 also does not intersect any other surfaces of the frame 130 such that the cavity sidewall 132b extending between the outer margin and the cavity floor 130a is spaced entirely inward from the outer side surfaces of the frame 130. However, according to some examples of the package, a portion or section of the cavity may alternatively intersect one or more of the outer side surfaces of the frame. Because the illustrated cavity 132 is rectangular in shape, the cavity sidewall 130b includes four (4) orthogonal sections. Of course, when an alternative cavity cross-sectional shape is utilized, the cavity sidewall may include a different number of straight sections, multiple curvilinear sections, or may be formed of single curved wall.

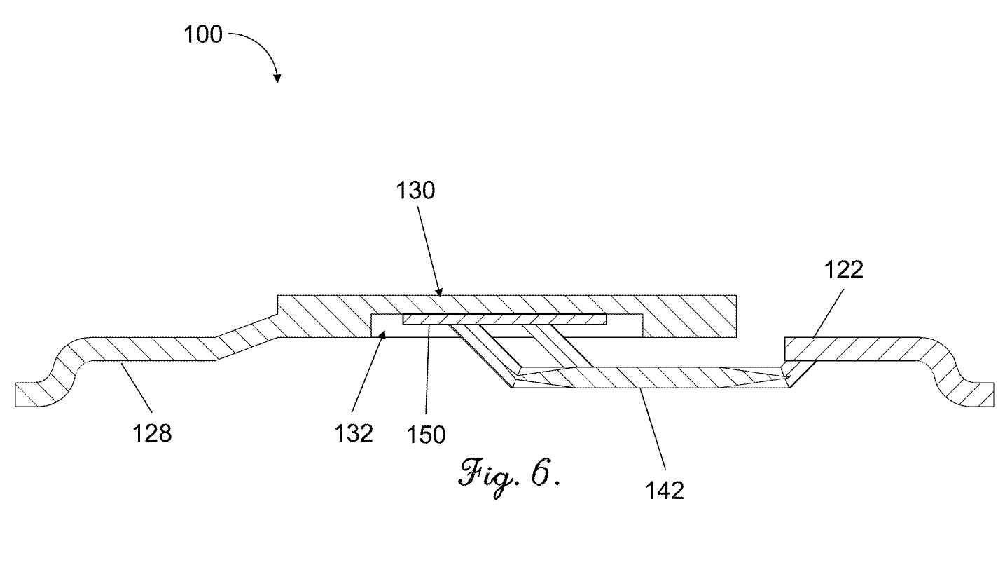

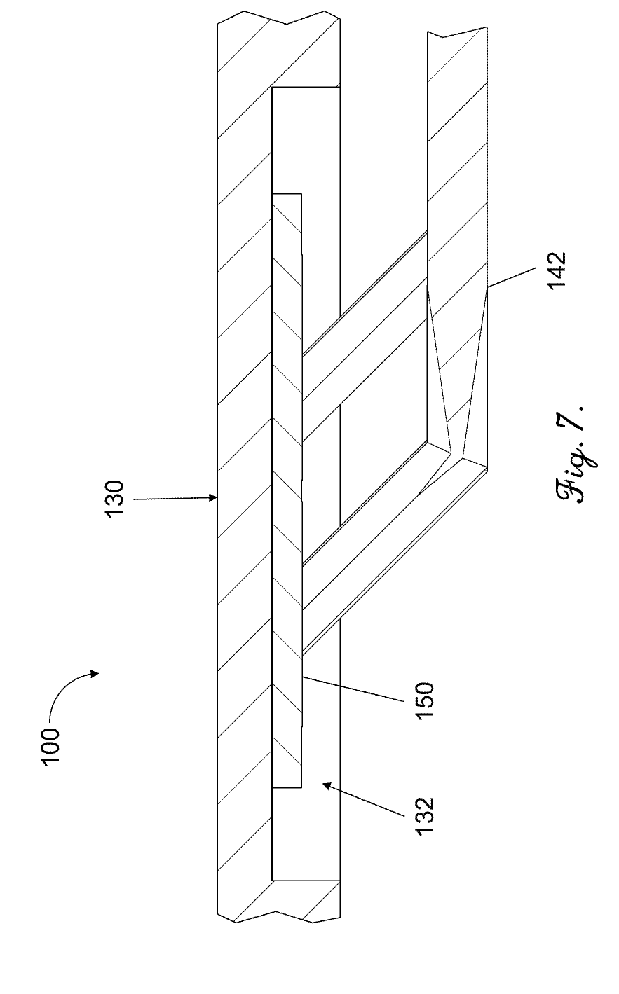

FIGS. 6 and 7 provide cross-sectional views of the electrical component package embodiment 100 shown in FIG. 3, with FIG. 7 particularly illustrating the package elements positioned within the cavity 132. The source leads 122 are electrically connected to the MOSFET 150 by the source wires 142, and the drain leads 128 are electrically connected to the MOSFET 150 through the electrically conductive frame 130. The MOSFET 150 may be positioned entirely within the cavity 132 and in direct physical contact with the frame 130. In this illustrated example, the “extra” space provided within the cavity 132 above the MOSFET 150 may accommodate or allow for alternative electrical connection with the MOSFET (e.g., thicker wiring, alternative wire configurations and/or spacing, etc.), without requiring the casing 110 to be enlarged to cover such alternative electrical connections. In other examples, the MOSFET may be positioned in part or entirely within an extruded area above the cavity 132. The extruded area shall be interpreted to mean the area of the casing 110 which is just outside the cavity 132 and is bounded by a projection of the outer margin of the cavity. The illustrated extruded area may alternatively be described as a right rectangular prism, in which the base of the prism is defined by the outer margin of the cavity. Furthermore, in some examples, the extruded area may have an alternative shape (primarily as a consequence of an alternative cavity cross-sectional shape and/or an alternative casing shape). Such alternative extruded area shapes may include but not be limited to a right cylindrical prism, a right trapezoidal prism, a right triangular prism, or similar shape extended from the frame. The cavitary and extruded areas may cooperatively define a component-receiving space, and any elements positioned within the component-receiving space may be considered to be “aligned” with the cavity 132.

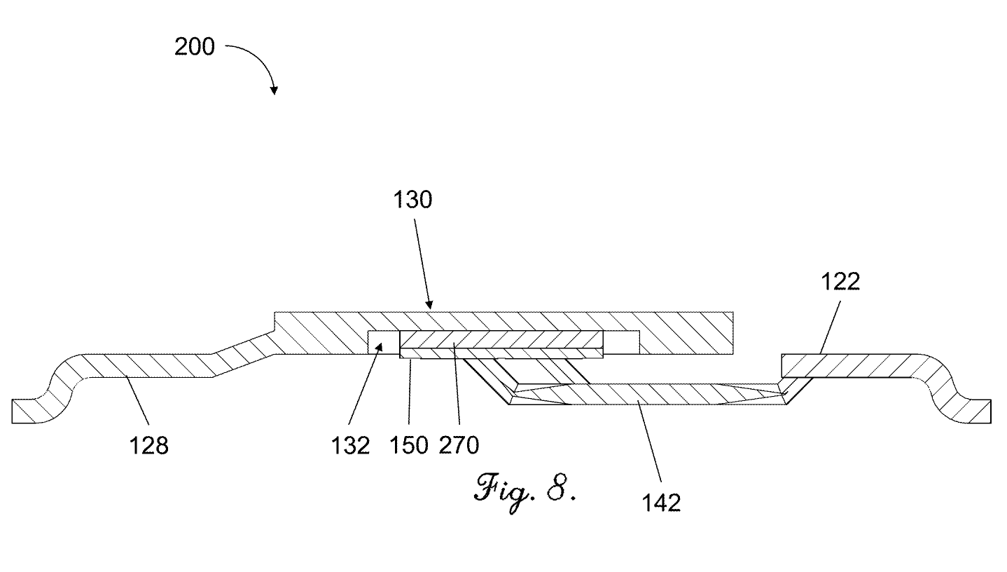

FIG. 8 illustrates a cross-sectional view of another example electrical component package 200 including a frame 130 and a MOSFET 150 (or alternative electrical component). It is initially noted that, with certain exceptions to be discussed in detail below, many of the elements of the electrical component package 200 are the same or very similar to those described in detail above in relation to the electrical component package 100 depicted in FIGS. 1-7. Therefore, for the sake of brevity and clarity, redundant descriptions and numbering will be generally avoided here. Unless otherwise specified, the detailed descriptions of the elements presented above with respect to the electrical component package 100 should therefore be understood to apply at least generally to the electrical component package 200, as well.

An electrical device 270 may be interposed between the MOSFET 150 and the frame 130. The example illustrated in FIG. 8 depicts a single device 270, but other examples contemplate multiple devices positioned between the frame 130 and MOSFET 150. Furthermore, according to some examples, the arrangement may be reversed, with the MOSFET 150 being located between the device 270 and the frame 130. The electrical device 270 may contact both the MOSFET 150 and the frame 130, and the MOSFET 150 may be spaced entirely away from the frame 130. The electrical devices 270 may include transistors, diodes, capacitors, semiconductor dies, and isolated substrates, without restriction. An example may include an electrical device 270 that is an electrically insulative and/or thermally conductive material, such as a ceramic substrate. With a ceramic, electrically insulating device, the frame may be entirely isolated (physically and/or electrically) from the electrical connector. In some examples, the electrical device 270 and the MOSFET 150 may be positioned entirely within the cavity 132. In other examples, the electrical device and/or MOSFET may be configured so that part or all of the MOSFET is positioned within an extruded area just outside the cavity. In FIG. 8, the extruded area of the package is defined by a portion of a casing in the same manner as the extruded area of the first example (shown in FIGS. 1-7). In yet more examples, part of the electrical device may also be positioned within the extruded area of the package. The presence of the cavity 132 may allow the use of electrical devices 270 that would otherwise be too large to mount on the frame 130, in combination with the MOSFET 150, without increasing the height of the package 200.

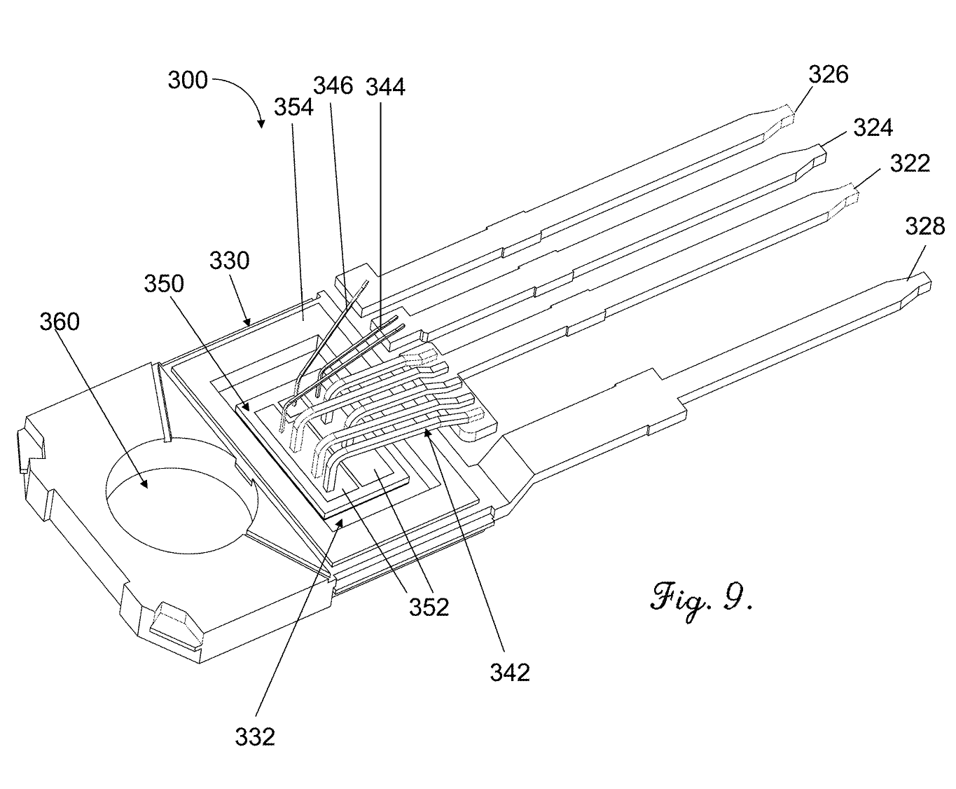

FIG. 9 illustrates another example electrical component package 300 which may have a so-called “TO-247” package configuration. It is initially noted that, with certain exceptions to be discussed in detail below, many of the elements of the electrical component package 300 are the same or very similar to those described in detail above in relation to the electrical component packages 100 and 200 depicted in FIGS. 1-8. Therefore, for the sake of brevity and clarity, redundant descriptions and numbering will be generally avoided here. Unless otherwise specified, the detailed descriptions of the elements presented above with respect to the electrical component packages 100 and 200 should therefore be understood to apply at least generally to the electrical component package 300.

A MOSFET 350 is electrically connected to and placed in direct contact with a frame 330. Source pads 352 of the MOSFET 350 are electrically connected to a source lead 322 by respective source wires 342. The MOSFET 350 is similarly connected to a Kelvin connection lead 324 by a Kelvin connection wire 344 and to the gate lead 326 by a gate wire 346. A mounting hole 360 passes through a section of the frame 330. In the embodiment, the frame 330 is made of an electrically conductive material and electrically connects the MOSFET 350 to a drain lead 328. In other examples, the MOSFET may be substituted with a different electrical component, and the leads and connections may be changed or rearranged to accommodate the different electrical component. The MOSFET (or alternative electrical component) may also be combined with another device. Yet further, the frame may be made of an electrically insulative material with a different means to connect the MOSFET to the drain lead, such as a wire.

In this particular illustrated example, the MOSFET 350 rests in a cavity 332 in the frame 330. The cavity 332 has a rectangular cross-sectional shape and outer margin, with the latter being coplanar with the frame surface 354 from which the cavity 332 extends. The MOSFET 350 may be contained entirely within the cavity 332, with the wires 342, 344, and 346 extending into the cavity 332 for connection to the MOSFET 350. In other examples, the MOSFET 350 may be positioned partially or entirely above the outer margin of the cavity 332.

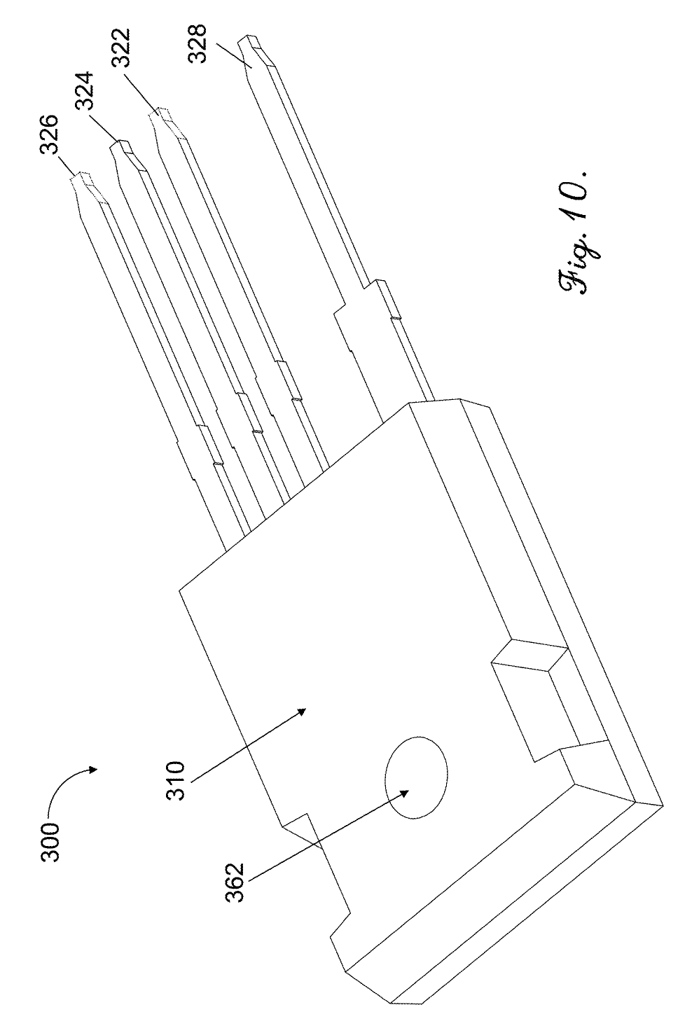

FIG. 10 shows the electrical component package 300 with a protective casing 310 molded around the frame 330, as well as the wires 342, 344, and 346 and the MOSFET 350. The casing 310 may include a casing hole 362 which is coaxial (or at least generally aligned) with the mounting hole 360. A heat sink (not shown) may pass through the casing hole 362 and the mounting hole 360. The frame 330 may be entirely encapsulated within the casing 310. However, according to certain examples, the frame 330 may be partially exposed. For example, a portion of the frame 330 (e.g., at least part of the frame side not visible in FIG. 10) may not be covered by the casing 310. The frame 330 may be made of a thermally conductive material and be attached to a heat dissipation apparatus (not shown), such as the heat sink extending through the aligned holes 360,362 and/or another heat sink contacting (or thermally coupled to) the exposed surface of the frame.

Applications of this technology may include “low profile” electrical component packages that have a restricted height (e.g., because the package is used in a setting with limited space). In particular, this technology may be applied to improve performance in electrical component packages that have a height of two and one-half millimeters (2.5 mm) or less.

### FEATURE COMBINATIONS

According to various examples of the present disclosure, an electrical component package may include an electrical component, an electrical connector, and a frame. The electrical connector may be electrically coupled with the electrical component. The frame may support the electrical component. The frame may present a cavity. The electrical component may be at least in part aligned with the cavity.

In combination with the previous example, the electrical component package may include a device interposed between the electrical component and the frame, with the electrical component being spaced apart from the frame. The device may contact the electrical component and the frame.

In combination with any of the previous examples, the device may comprise ceramic.

In combination with any of the previous examples, the device may comprise a semiconductive material.

In combination with any of the previous examples, the device may comprise a die.

In combination with any of the previous examples, the electrical component may be positioned at least in part within the cavity.

In combination with any of the previous examples, the electrical component package may include a casing. The casing may encapsulate at least part of the frame. The frame may define an outer cavity margin from which the cavity extends. The cavity may present a cavitary area inward from the cavity margin. The casing may present an extruded area projecting from the cavity margin. The cavitary area and the extruded area may cooperatively define a component-receiving space. The electrical component may be positioned in the component-receiving space.

In combination with any of the previous examples, the electrical component may be positioned at least in part within the cavitary area.

In combination with any of the previous examples, the electrical connector may be positioned at least in part within the extruded area.

In combination with any of the previous examples, the electrical connector may be positioned at least in part within the cavitary area.

In combination with any of the previous examples, the casing may comprise epoxy resin.

In combination with any of the previous examples, the electrical component may comprise a transistor.

In combination with any of the previous examples, the electrical component may comprise a field-effect transistor.

In combination with any of the previous examples, the electrical connector may include at least one lead.

In combination with any of the previous examples, at least one lead may be a pin.

In combination with any of the previous examples, the frame may form at least part of the electrical connector.

In combination with any of the previous examples, the frame may comprise an electrically insulative material.

In combination with any of the previous examples, the electrical component may directly contact the frame.

In combination with any of the previous examples, the electrical connector may include a wire.

In combination with any of the previous examples, the electrical component package may have a height of 2.5 millimeters or less.

### GENERAL CONSIDERATIONS

In this description, references to “one embodiment,” “an embodiment,” “embodiments,” “an example,” “one example,” or “examples” mean that the feature or features being referred to are included in at least one embodiment or example of the technology. Separate references to “one embodiment,” “an embodiment,” “embodiments,” “an example,” “one example,” or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

It is to be understood that the features of the various embodiments described herein may be combined with each other, unless specifically noted otherwise.

Terms such as “first,” “second,” and the like, are used to describe various elements, regions, sections, etc. and are also not intended to be limiting. Like terms refer to like elements throughout the description.

Terms of relative location and direction (e.g., above, below, left, right, upper, lower, vertical, lateral) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Although the present application sets forth a detailed description of numerous different examples, it should be understood that the legal scope of the description is defined by the words of the claims set forth at the end of this patent and equivalents. The detailed description is to be construed as illustrative only and does not describe each possible example since describing each possible example would be impractical. Numerous alternative examples may be implemented, using either current technology or technology developed after the filing date of this patent, which would still fall within the scope of the claims.

The patent claims at the end of this patent application are not intended to be construed under 35 U.S.C. § 112(f) unless traditional means-plus-function language is expressly recited, such as “means for” or “step for” language being explicitly recited in the claim(s).

What is claimed is:

1. An electrical component package comprising:
an electrical component;
an electrical connector electrically coupled with the electrical component; and
a frame supporting the electrical component,
said frame presenting a cavity,
the electrical component being at least in part aligned with the cavity.

2. The electrical component package of claim 1, comprising;
a device interposed between and contacting the electrical component and the frame, with the electrical component being spaced apart from the frame.

3. The electrical component package of claim 2,
the device comprising ceramic.

4. The electrical component package of claim 2,
the device comprising a semiconductive material.

5. The electrical component package of claim 4,
the device comprising a die.

6. The electrical component package of claim 1,
the electrical component positioned at least in part within the cavity.

7. The electrical component package of claim 1, comprising;
a casing encapsulating at least part of the frame,
the frame defining an outer cavity margin from which the cavity extends,
the cavity presenting a cavitary area inward from the cavity margin,
the casing presenting an extruded area projecting from the cavity margin,
the cavitary area and the extruded area cooperatively defining a component-receiving space,
the electrical component being positioned in the component-receiving space.

8. The electrical component package of claim 7,
the electrical component positioned at least in part within the cavitary area.

9. The electrical component package of claim 8,
the electrical connector positioned at least in part within the extruded area.

10. The electrical component package of claim 7,
the electrical connector positioned at least in part within the cavitary area.

11. The electrical component package of claim 7,
the casing comprising epoxy resin.

12. The electrical component package of claim 1,
the electrical component comprising a transistor.

13. The electrical component package of claim 12,
the electrical component comprising a field-effect transistor.

14. The electrical component package of claim 1,
the electrical connector comprising at least one lead.

15. The electrical component package of claim 14,
the at least one lead being a pin.

16. The electrical component package of claim 1,
the frame forming at least part of the electrical connector.

17. The electrical component package of claim 1,
the frame comprising an electrically insulative material.

18. The electrical component package of claim 1,
the electrical component directly contacting the frame.

19. The electrical component package of claim 1,
the electrical connector comprising a wire.

20. The electrical component package of claim 1,
the package having a height of 2.5 millimeters or less.
